(19) United States
(12) Patent Application Publication
(10) Pub. No.: US 2014/0332063 A1
(43) Pub. Date: Nov. 13, 2014

(54) MULTILAYER POLYAMIDE FILM FOR REAR PANEL OF PHOTOVOLTAIC MODULE

(71) Applicant: ARKEMA FRANCE, Colombes (FR)

(72) Inventors: Samuel Devisme, Rouen (FR); Thibaut Montanari, Menneval (FR); Stéphane Bizet, Barc (FR)

(73) Assignee: ARKEMA FRANCE, Colomes (FR)

(21) Appl. No.: 14/361,507

(22) PCT Filed: Nov. 27, 2012
(86) PCT No.: PCT/FR2012/052725

§ 371 Date: May 29, 2014

(30) Foreign Application Priority Data
Nov. 30, 2011 (FR) 1160938

(51) Int. Cl. H01L 31/048

(52) U.S. Cl. CPC H01L 31/0487; H01L 31/048; H01L 31/0481
USPC 136/251; 136/256

(57) ABSTRACT

The use of a multilayer polyamide film as a rear protective sheet in a photovoltaic module. Also, a photovoltaic module containing photovoltaic cells protected by an encapsulant, a front protective layer, and a rear protective layer, wherein the rear protective layer is formed by a multilayer polyamide film including: a CA layer including, as predominant polymer, at least one polyamide A exhibiting a mean number of carbon atoms per nitrogen atom of between 4 and 8, a CB layer including: (a) as predominant polymer, at least one polyamide B exhibiting a mean number of carbon atoms per nitrogen atom of between 8 and 15, the polyamide(s) B exhibiting a mean number of carbon atoms per nitrogen atom which is strictly greater than the mean number of carbon atoms per nitrogen atom of the polyamide(s) A, and (b) at least one additive for combating UV radiation.

### TECHNICAL FIELD

Embodiments of the disclosure relate to the use of a multilayer film based on polyamides as rear protective sheet in a photovoltaic module. Embodiments of the disclosure also relate to a photovoltaic module including photovoltaic cells protected by an encapsulant, a front protective sheet and a rear protective sheet, in which the rear protective sheet consists of a multilayer film based on polyamides.

### BACKGROUND

Global warming, related to the greenhouse gases given off by fossil fuels, has led to the development of alternative energy solutions which do not emit such gases during the operation thereof, such as, for example, photovoltaic modules. The latter can be used effectively to supply electricity to a dwelling or to provide electricity to devices which cannot be connected to the electrical circuit, such as cell phones, ticket machines, bus shelters, and the like.

A photovoltaic module, or solar panel, is an electrical generator which makes it possible to convert solar energy into a direct current, composed of an assembly of photovoltaic cells based on a semiconductor material, such as silicon, which cells are connected to one another electrically and are protected by an adhesive encapsulating material, generally based on ethylene/vinyl acetate (EVA) copolymer or optionally based on a blend of polyethylene and of a functionalized polyolefin (WO 2010/067040). An upper protective sheet and a protective sheet at the back of the module (or backsheet) are positioned against each face of the encapsulant. Protection of the photovoltaic cell from impact and moisture is provided by the front protective sheet, generally made of glass or fluoropolymer, while the role of the rear protective sheet is also to protect the cell against moisture but also to ensure electrical insulation of the cells, to block UV rays and to present a good mechanical strength, in particular to tearing. This rear protective sheet thus plays an essential role in the longevity of the photovoltaic module.

The most effective solution currently consists in using, as rear protective sheet, three-layered structures including a central layer based on polyester, such as polyethylene terephthalate (PET), providing electrical insulation of the photovoltaic module and the mechanical stability of the rear protective sheet, which is surrounded by two layers based on fluoropolymer, such as polyvinylidene fluoride (PVDF), polyvinyl fluoride (PVF) or poly(ethylene/tetrafluoroethylene) (ETFE), which are intended to protect the central layer against hydrolysis and to provide the function of protection of the protective sheet from UV radiation. This rear protective sheet exhibits in particular a good dimensional stability at the temperatures of rolling the photovoltaic module.

More recently, other materials for manufacturing the rear protective sheet of photovoltaic modules have been provided, such as polyolefins, in particular polypropylene (WO 2010/053936 and WO 2011/09568), which are optionally grafted with polyamide (WO 2010/069546). These protective sheets can additionally include a polyamide. However, their performances are not optimal.

A suggestion has also been made to replace the PVDF layers of the conventional structures with layers of polyamide 12 (PA-12) which are presented as thinner and less expensive (US 2010/119841 and US 2010/059105). Structures of this type are sold in particular by Isovoltaic under the commercial references ICOSOLAR® APA 3636 and APA 3552. As indicated above, the central PET layer nevertheless has a tendency to hydrolyze and, consequently, to depolymerize under certain moisture conditions. This disadvantage has been overcome by the structure sold by Isovoltaic under the reference ICOSOLAR® AAA 3554, which includes a central PA-12 layer. However, it has been demonstrated that this type of structure, comprising three PA-12 layers, exhibits a tendency to relax/creep at the temperatures employed to manufacture the photovoltaic module. This is because the process for the manufacture of the module generally comprises a stage of extrusion of the rear protective sheet and then of rolling, at high temperature and under vacuum, the various sheets forming the module, at a temperature sufficient to soften the encapsulating material. It has been observed that, at this temperature, the PA-12 in ICOSOLAR® AAA 3554 has a tendency to retract. In order to overcome this disadvantage, glass fibers have been added to the central PA-12 layer in order to increase its viscosity and its heat deflection temperature. The reinforcing of the central layer has nevertheless rendered the rear protective sheet more brittle, which is not desirable. The document US 2010/0324207 furthermore describes the use of a monolayer structure based on C₈-C₁₇ polyamide as rear protective sheet. This structure presents the same problems of retraction as that described above.

The document EP 2422976, which can be cited in opposition solely under novelty, which in particular does not disclose the characteristics of the CB layer of claim 1 of the patent application in question, is also known.

Certain embodiments of the disclosure are targeted at overcoming the disadvantages of the rear protective sheets of photovoltaic modules by providing for the use, in their manufacture, of a multilayer film based on two different types of polyamide which exhibits all the properties required for this use, in particular a low water uptake, sufficient electrical insulation and efficient protection against UV radiation, at an acceptable cost, in particular even lower than that of the PA12/PA12/PA12 multilayer structures, without, however, exhibiting the problems of retraction observed with the rear protective sheets including a central layer based on PA-12.

### SUMMARY

An embodiment of the disclosure is thus the use of a multilayer film as rear protective sheet in a photovoltaic module comprising photovoltaic cells covered with an encapsulant, characterized in that said film comprises:
a CA layer including, as predominant polymer, at least one polyamide A exhibiting a mean number of carbon atoms per nitrogen atom of between 4 and 8,
a CB layer including: (a) as predominant polymer, at least one polyamide B exhibiting a mean number of carbon atoms per nitrogen atom of between 8 and 15, the polyamide(s) B exhibiting a mean number of carbon atoms per nitrogen atom which is strictly greater than the mean number of carbon atoms per nitrogen atom of the polyamide(s) A, and (b) at least one additive for combating UV radiation,
the CB layer being positioned between the encapsulant and the CA layer.

Another embodiment of the disclosure is a photovoltaic module including photovoltaic cells protected by an encapsulant, a front protective sheet and a rear protective sheet, in which the rear protective sheet consists of a multilayer film comprising:
a CA layer including, as predominant polymer, at least one polyamide A exhibiting a mean number of carbon atoms per nitrogen atom of between 4 and 8,
a CB layer including: (a) as predominant polymer, at least one polyamide B exhibiting a mean number of carbon atoms per nitrogen atom of between 8 and 15, the polyamide(s) B exhibiting a mean number of carbon atoms per nitrogen atom which is strictly greater than the mean number of carbon atoms per nitrogen atom of the polyamide(s) A, and (b) at least one additive for combating UV radiation,
the CB layer being positioned between the encapsulant and the CA layer.

It is specified that, throughout this description, the expression “of between” must be understood as including the limits mentioned. In addition, by misuse of language, the term “film” includes not only films proper, generally having a thickness of less than 250 μm, and sheets, the thickness of which is instead of between 250 and 1 mm.

### DETAILED DESCRIPTION

According to the present patent application, the term “polyamide”, also denoted PA, is targeted at:
homopolymers obtained by polycondensation of aliphatic diamines and aliphatic diacids, or of a lactam or of an α,γ-aminocarboxylic acid,
copolymers, or copolyamides, based on different amide units, such as, for example, copolyamide 6/12 with amide units derived from lactam-6 and lactam-12,
polyamide compositions, such as polyamide alloys, provided that the polyamide is the predominant constituent thereof.

There also exists a category of copolyamides within a broad sense which, although not preferred, comes within the context of the disclosure. They are copolyamides comprising not only amide units (which are predominant) but also units of nonamide nature, for example ether units. The best known examples are PEBAs or polyether-block-amides, and their copolyamide-ester-ether, copolyamide-ether or copolyamide-ester variants. Mention may be made, among these, of PEBA-12, where the polyamide units are the same as those of PA-12, and PEBA-6.12, where the polyamide units are the same as those of PA-6.12.

In this disclosure, the homopolyamides, copolyamides and alloys having a given number of carbon atoms per nitrogen atom are selected, it being known that there are as many nitrogen atoms as amide (—CO—NH) groups.

In the case of a homopolyamide of PA-X.Y type, the number of carbon atoms per nitrogen atom is the mean of the X unit and of the Y unit. Thus, PA-6.12 is a PA comprising 9 carbon atoms per nitrogen atom, in other words is a C₉ PA. PA-6.13 is a C_{9.5} PA. PA-12.T is a C₁₀ PA, the T, that is to say terephthalic acid, being a C₈ group.

In the case of the copolyamides, the number of carbon atoms per nitrogen atom is calculated according to the same principle. The calculation is carried out on a molar pro rata basis from the various amide units. Thus, 60/40 mol % coPA-6.T/6.6 is a C_{6.6} copolyamide: 60%×(6+8)/2+40%×(6+6)/2=6.6. In the case of a copolyamide having units of nonamide type, the calculation is carried out solely on the portion of amide units. Thus, in the case of PEBA-12, which is a block copolymer of amide-12 units and of ether units, the carbon number will be 12; for PEBA-6.12, it will be 9.

In the case of the mixtures or alloys, the calculation of the number of carbon atoms per nitrogen atom is carried out solely on the fraction consisting of the polyamides. For example, a composition with 67 parts by weight of PA-12 (12 carbon atoms per nitrogen atom) and 33 parts by weight of PA-6 (6 carbon atoms per nitrogen atom) will be a polyamide composition comprising 10 carbon atoms per nitrogen atom, in other words a C₁₀ composition. The calculation is as follows: 12×67/(67+33)+6×33/(67+33). In the case of a similar composition but comprising, in addition, 40 parts of impact modifier EPR, which is not a polyamide, the number of carbon atoms per nitrogen atom will be equal to 10.

Homopolyamides are preferred for use as the polyamide A.

The film used according to embodiments of the disclosure includes a CA layer comprising, as predominant polymer, at least one polyamide A exhibiting a mean number of carbon atoms per nitrogen atom of between 4 and 8. The term “predominant” is understood to mean that the proportion by weight of the polyamide A in the CA layer is greater than that of any other polymer present in said layer. Generally, polyamide A represents more than 30% by weight, for example more than 60% by weight, indeed even more than 90% by weight, with respect to the weight of the CA layer, and the polyamide B represents more than 50% by weight, for example more than 70% by weight, indeed even more than 90% by weight, with respect to the weight of the CB layer.

Examples of polyamides A are in particular PA-6, PA-8, PA-6.6, PA-4.6, PA-6.10, copolyamide-6.T/6.6, copolyamide 6.I/6.6 and copolyamide 6.T/6.I/6.6, where 1 represents isophthalic acid and T represents terephthalic acid, and their blends. It is preferable to use PA-6. The melting point of the polyamide A is preferably greater than or equal to 210° C.

The film used according to embodiments of the disclosure additionally includes a CB layer including, as predominant polymer, at least one polyamide B exhibiting a mean number of carbon atoms per nitrogen atom of between 8 and 15, the polyamide(s) B exhibiting a mean number of carbon atoms per nitrogen atom strictly greater than the mean number of carbon atoms per nitrogen atom of the polyamide(s).

Examples of polyamide B are in particular PA-8, PA-9, PA-11, PA-12, PA-6.10, PA-10.10, PA-10.12, PA-6.12, PA-6.14, PA-6.18, copolyamide 12/10.T, copolyamide 11/10.T or polyamide-12.T. It is preferable to use polyamides having a mean number of 11 to 15 carbon atoms per nitrogen atom, such as PA-12.

The polyamides A and B described above can be obtained, in all or part, from resources resulting from renewable starting materials, that is to say comprising organic carbon of renewable origin determined according to the standard ASTM D6866. It is the case in particular for the sebacic acid used in PA-6.10 or the aminoundecanoic acid which results in PA-11, both resulting from castor oil.

The CB layer and optionally also the CA layer also includes at least one additive for combating UV radiation. The latter can be chosen in particular from opacifying organic fillers, organic UV absorbers, UV stabilizers of HALS type (that is to say, based on sterically hindered amine) and their mixtures. Such additives are available in particular from BASF under the TINUVIN® and UVINUM® commercial references. The additive for combating UV radiation can represent from 0.1% to 10% by weight, preferably from 0.1% to 5% by weight, with respect to the total weight of the CB or CA layer under consideration. Inorganic fillers can also be used. They can be chosen from titanium dioxide, zinc dioxide, zinc oxides or sulfides, silica, quartz, alumina, calcium carbonate, talc, mica, dolomite (CaCO₃—MgCO₃), montmorillonite (aluminosilicate), barium sulfate (BaSO₄), ZrSiO₄, Fe₃O₄ and their mixtures. In this case, the filler or fillers for combating UV radiation preferably represent from 0.1% to 50% by weight, preferably from 5% to 30% by weight, with respect to the total weight of the CB or CA layer under consideration.

Furthermore, at least one of the CA and CB layers (preferably the CA layer) can be formulated so as to render it adherent, respectively, to the CB layer or to the CA layer (and/or to the encapsulant). In order to do this, it is preferable for the CA layer to additionally include a minor amount of polyamides AT and optionally A″, where:
(i) A′ exhibits a mean number of carbon atoms per nitrogen atom of between 7 and 10 and strictly greater than that of A, and
(ii) A″ exhibits a mean number of carbon atoms per nitrogen atom of between 9 and 18 and strictly greater than that of A′.

Likewise, the CB layer can include a minor amount of polyamides B′ and B″, which respectively exhibit a mean number of carbon atoms per nitrogen atom of between 4 and 8.5 and strictly less than that of B″ and of between 7 and 10 and strictly less than that of B.

The difference in the mean number of carbon atoms per nitrogen atom between A and A′, between A′ and A″, between B′ and B″ and between B″ and B can be of between 1 and 4, preferably between 2 and 3. The weighted mean of the enthalpies of fusion of these polyamides within the CA or CB composition is advantageously greater than 25 J/g (measured by DSC). Each of the polyamides A, A′, A″, B, B′ and B″ can be a random, alternating or block polymer. They are preferably aliphatic polymers. Examples of such polyamides can be chosen from the lists indicated above.

It is thus preferable for the CA layer rendered adherent to include the following proportions by weight of A, AT and A″:
A (such as PA-6)=65-85%
AT (such as PA-6.12)=3-8%
A″ (such as PA-12)=12-30%,
per 100% by weight of the A+A′+A″ blend.

In an alternative form, it is possible to include at least one tie layer in the multilayer film in order to cause the CB layer to adhere to the CA layer and/or to the encapsulant and/or to cause the CA layer to adhere to the CB layer. Examples of suitable ties can be chosen from:
one or more copolyamides comprising at least 25% by weight of at least one monomer having a mean number of carbon atoms per nitrogen atom of 4 to 6 and at least 25% by weight of at least one comonomer having a mean number of carbon atoms per nitrogen atom of 9 to 18 and their mixtures, such as the following copolyamides: coPA-6/12 30/70%, coPA-6/12 50/50%, coPA-6/12 75/25%, coPA-6/6.10/12 25/50/25% and coPA-6/7/12 25/50/25%, and their blends, such as the blend of coPA-6/12 80/20% and coPA-6/12 20/80%;
one or more homopolyamides of PA-X.Y type, where X ranges from 4 to 6 and Y ranges from 8 to 18, such as PA-6.12, and their blends including at least 25% by weight of diamine units for which X ranges from 4 to 6 and at least 25% by weight of diacid units for which Y ranges from 8 to 18, such as the blends of PA-6.12 and PA-6.10, the blends of PA-6.6 and PA-6.18 and the blends of PA-6.6, PA-6.12 and PA-12.12;
a blend of polyamides, such as described in particular in the application EP 2 098 580, especially a blend of PA-6, PA-6.12 and PA-12;
at least one functionalized polyolefin; and
a blend of polyamide(s) and completely or partially functionalized polyolefin(s), such as the blends of PA-6, PA-12 and functionalized polyolefin and the blends of PA-6.12, PA-6 and functionalized polyolefin.

Examples of functionalized polyolefins comprise a copolymer of at least one α-olefin, such as ethylene or propylene, with at least one comonomer carrying a reactive functional group chosen in particular from a carboxylic acid, such as (meth)acrylic acid, a carboxylic anhydride, such as maleic anhydride, or an epoxide, such as glycidyl (meth)acrylate, and optionally at least one other comonomer not carrying a reactive functional group chosen, for example, from a different α-olefin; a diene, such as butadiene; an unsaturated carboxylic acid ester, such as an alkyl (meth)acrylate where the alkyl group can be a methyl, ethyl or butyl group, in particular; and a carboxylic acid vinyl ester, such as vinyl acetate.

It is preferable for the functionalized polyolefin to include from 60% to 100% by weight of α-olefin and from 0% to 40% by weight, preferably from 0% to 15% by weight, of comonomer not carrying a reactive functional group. In addition, it is preferable for the functionalized polyolefin to include from 0.1% to 15% by weight, preferably from 0.5% to 5% by weight, of comonomer carrying a reactive functional group. Examples of such functionalized polyolefins are the ethylene/acrylic ester/glycidyl methacrylate and ethylene/acrylic ester/maleic anhydride copolymers respectively available from Arkema under the trade name LOTADER® GMA and LOTADER® MAH, in particular LOTADER® AX 8840. Another example of tie is the ethylene/alkyl acrylate/acrylic acid terpolymer available from BASF under the trade name LUCALEN® A 3110 M. Mention may also be made of the ethylene/vinyl acetate copolymers modified with maleic anhydride available from Arkema under the OREVAC® trade name.

The composition of the CA and/or CB layers of the film used according to embodiments of the disclosure can additionally include various additives, including inorganic or organic pigments, dyes, optical brighteners, coupling agents, crosslinking agents, plasticizers, such as butylbenzenesulfonamide (BBSA), heat stabilizers, stabilizers with regard to hydrolysis, antioxidants (for example of phenol and/or phosphite and/or amine type), reinforcements, such as glass fiber, flame retardants and their mixtures. On the other hand, it is preferable for these layers not to include a copper-based stabilizer.

The CA and/or CB layers advantageously additionally include at least one impact modifier advantageously chosen from functionalized polyolefins, for example polyolefins functionalized by a carboxylic acid, such as (meth)acrylic acid, a carboxylic anhydride, such as maleic anhydride, or an epoxide, such as glycidyl (meth)acrylate. Examples of such impact modifiers comprise the functionalized polyolefins described above as ties. The impact modifier can represent from 2% to 40% by weight, with respect to the total weight of the layer comprising it.

The film used according to embodiments of the disclosure can have a bilayer structure comprising only the CA and CB layers. However, according to a preferred embodiment of the disclosure, it can assume a structure comprising three layers, consisting of a CA layer coated with a CB layer on each of its faces. The thickness of each of the CA and CB layers can, for example, be of between 15 μm and 500 μm, for example between 20 and 350 μm, the multilayer film having a total thickness of 200 to 1500 μm, for example from 350 to 500 μm. In addition, it can comprise layers other than the CA and CB layers and the optional tie layers, such as layers forming a barrier to water, in particular an aluminum sheet, or also one or more layers based on a polyolefin, such as polypropylene or high-density polyethylene, optionally grafted with polyamide. However, it is preferable for the film according to embodiments of the disclosure not to include a layer based on ethylene/vinyl alcohol (EVOH) copolymer.

The film used according to embodiments of the disclosure can be manufactured according to conventional techniques for producing films, sheets or plaques. Mention may be made, by way of examples, of the techniques of blown film extrusion, extrusion-lamination, extrusion-coating, cast film extrusion or also extrusion of sheets. All these techniques are known to a person skilled in the art and he will know how to adjust the processing conditions of the various techniques (temperature of the extruders, connector, dies, rotational speed of the screws, cooling temperatures of the cooling rolls, and the like) in order to form the structure according to embodiments of the disclosure having the desired shape and the desired thicknesses. It would not be departing from the disclosure if the final structure were obtained by pressing or rolling techniques with adhesives in the solvent or aqueous route or if the final structure were subjected to an additional stage of annealing. The film used according to embodiments of the disclosure can additionally be provided in the sheet or roll form.

The film according to embodiments of the disclosure can be used as rear protective sheet in a photovoltaic module. Such a photovoltaic module can be manufactured according to the processes known to a person skilled in the art and in particular as described in U.S. Pat. No. 5,593,532. In general, the assembling of the various layers can be carried out by hot or vacuum pressing, or hot rolling. The materials constituting the upper protective sheet and the encapsulant can also be chosen from those conventionally used in these applications. Thus, the upper protective layer can comprise glass, PMMA or a fluoropolymer and the encapsulant can comprise at least one polymer, such as an ethylene/vinyl acetate (EVA) copolymer, polyvinylbutyral (PVB), ionomers, poly(methyl methacrylate) (PMMA), a polyurethane, a polyester, a silicone elastomer and their blends. The photovoltaic cells can comprise monocrystalline or polycrystalline doped silicon, amorphous silicon, cadmium telluride, copper indium diselenide or organic materials, for example.

Embodiments of the disclosure will now be illustrated by the following nonlimiting example.

### EXAMPLE

Preparation and Evaluation of the Properties of Multilayer Films

Multilayer films having a thickness of between 350 and 450 μm are prepared by cast film extrusion on an extrusion line of Dr Collin brand. This extrusion line is composed of three extruders equipped with a standard polyolefin screw profile, with a variable coextrusion block and with a 250 mm coathanger die. The coextrusion block allows the production of a film of three layers (Layer 1/Layer 2/Layer 3) with a variable distribution of thicknesses (e.g.: 25/300/25 μm). The parameters of the process are set thus:
T° extrusion layers 1 and 3: 220° C.
T° extrusion layer 2: 220° C. or 240° C., according to the polymers to be extruded
T° coextrusion box and die: 240° C.
line speed: 3 m/min

A comparative monolayer film of the same thickness was in addition produced on the same line while feeding the 3 extruders with the same material. In this case, the parameters of the process were set thus:
T° extrusion layers 1 and 3: 240° C.
T° extrusion layer 2: 240° C.
T° coextrusion box and die: 240° C.
line speed: 3 m/min

The compositions of the different layers are as follows:

| | | Thicknesses of | |
|---|---|---|---|
| Structure | Compositions of the layers | the layers (μm) | Water uptake (%)* |
| Film 1 | PA12uv/PA6x/PA12uv | 25/300/25 | 5.8 |
| (according to an | | | |
| embodiment of the | | | |
| disclosure) | | | |
| Film A | PA12uv/PA12uv/PA12uv | 25/300/25 | 1.8 |
| (comparative) | | | |
| Film B | PA6uv | 350 | 9.1 |
| (comparative) | | | |
| Film 2 | PA12uv/tie/PA6/tie/ | 25/25/250/25/25 | 6.7 |
| (according to an | PA12uv | | |
| embodiment of the | | | |
| disclosure) | | | |
| Film C | PA12uv + TiO2/PA12uv + | 25/300/25 | 1.35 |
| (comparative) | TiO₂ + GF + PP/PA12uv + | | |
| | TiO₂ | | |
| Film 3 | PA12uv + TiO₂/PA6x + | 25/300/25 | 3.4 |
| (according to an | TiO₂ + GF + PP/PA12uv + TiO₂ | | |
| embodiment of the | | | |
| disclosure) | | | |
| Film D | PA6uv + TiO2/PA6x + TiO₂ + | 25/300/25 | 7.0 |
| (comparative) | GF + PP/PA6uv + TiO₂ | | |
| Film 4 | PA12uv + TiO₂/PA6x + | 25/300/25 | 4.8 |
| (according to an | TiO₂ + GF + PP/PA12uv + TiO₂ | | |
| embodiment of the | | | |
| disclosure) | | | |

*Measured after 15 days on the film steeped in water and expressed as percentage of increase in weight with respect to the dry specimen conditioned overnight at 80° C. under vacuum where:
“PA12uv” denotes a PA-12 composition stabilized toward UV radiation, including 99.15% of PA-12 with an MFI equal to 20 (under 5 kg at 235° C.), 0.2% of CIBA stabilizer TINUVIN ® 312, 0.15% of CIBA stabilizer IRGAFOS ® 168 and 0.5% of CIBA stabilizer IRGANOX ® 245,
“PA6uv” denotes a PA-6 composition stabilized toward UV radiation, including 99.15% of PA-6 with an MFI equal to 20 (under 2.16 kg at 235° C.), 0.2% of CIBA stabilizer TINUVIN ® 312, 0.15% of CIBA stabilizer IRGAFOS ® 168 and 0.5% of CIBA stabilizer IRGANOX ® 245,
“PA6x” denotes a PA-6 composition which has been rendered adherent, including 69.15% of PA-6 with an MFI equal to 20 (under 2.16 kg at 235° C.), 5% of PA-6.12 with an MFI equal to 10 (under 5 kg at 235° C.), 15% of PA-12 with an MFI equal to 6 (under 5 kg at 235° C.), 10% of copolymer of ethylene, ethyl acrylate and maleic anhydride in a ratio by weight 68.5/30/1.5 (MFI = 6 under 2.16 kg at 190° C.), 0.2% of CIBA stabilizer TINUVIN ® 312, 0.15% of CIBA stabilizer IRGAFOS ® 168 and 0.5% of CIBA stabilizer IRGANOX ® 245,
“PA12uv + TiO₂” denotes a composition including 79.15% of PA-12 with an MFI equal to 20 (under 5 kg at 235° C.), 20% of TiO₂ of TIOXIDE ® RTC30 type, 0.2% of CIBA stabilizer TINUVIN ® 312, 0.15% of CIBA stabilizer IRGAFOS ® 168 and 0.5% of CIBA stabilizer IRGANOX ® 245,
“PA12uv + TiO₂ + GF + PP” denotes a composition including 54.15% of PA-12 with an MFI equal to 55 (under 5 kg at 235° C.), 20% of TiO₂ of TIOXIDE ® RTC30 type, 10% of Asahi glass fibers FT692, 15% of Mitsui polypropylene grafted with maleic anhydride ADMER ® QB520E, 0.2% of CIBA stabilizer TINUVIN ® 312, 0.15% of CIBA stabilizer IRGAFOS ® 168 and 0.5% of CIBA stabilizer IRGANOX ® 245,
“Tie” denotes a composition including 79.15% of PA-6.12 with an MFI equal to 10 (under 5 kg at 235° C.), 15% of PA-6 with an MFI equal to 5 (under 5 kg at 235° C.), 5% of copolymer of ethylene, ethyl acrylate and maleic anhydride in a ratio by weight 68.5/30/1.5 (MFI = 6 under 2.16 kg at 190° C.), 0.2% of CIBA stabilizer TINUVIN ® 312, 0.15% of CIBA stabilizer IRGAFOS ® 168 and 0.5% of CIBA stabilizer IRGANOX ® 245,
“PA6x + TiO₂ + GF + PP” denotes a composition including 34.15% of PA-6 with an MFI equal to 20 (under 2.16 kg at 235° C.), 3% of PA-6.12 with an MFI equal to 10 (under 5 kg at 235° C.), 12% of PA-12 with an MFI equal to 6 (under 5 kg at 235° C.), 5% of copolymer of ethylene, ethyl acrylate and maleic anhydride in a ratio by weight 68.5/30/1.5 (MFI = 6 under 2.16 kg at 190° C.), 20% of TiO₂ of TIOXIDE ® RTC30 type, 10% of Asahi glass fibers FT692, 15% of Mitsui polypropylene grafted with maleic anhydride ADMER ® QB520E, 0.2% of CIBA stabilizer TINUVIN ® 312, 0.15% of CIBA stabilizer IRGAFOS ® 168 and 0.5% of CIBA stabilizer IRGANOX ® 245.

The abovementioned films are subject to an evaluation of their thermomechanical stability, of their permeability to water vapor and of their water uptake under conditions corresponding to use in photovoltaic panels, according to the following protocols.

Thermomechanical Stability

The thermomechanical strength of the various films is evaluated by dynamic mechanical analysis. This test consists in measuring the storage and loss moduli of the material as a function of the temperature at a given stressing frequency. For this, the DMA Q800 device from TA is used. The measurements are carried out on the films in tension at a stressing frequency of 1 Hz. The storage and loss moduli are measured according to a temperature gradient of 3° C./min ranging from −40° C. to a temperature of greater than 150° C. which depends on a melting point of the formulation. The thermomechanical strength at 150° C. (typical temperature for lamination of photovoltaic modules) of the various formulations is evaluated through the storage modulus at 1 Hz measured at this temperature.

Permeability to Water Vapor

The permeability to water vapor (for “Moisture Vapor Transmission Rate” or MVTR) is measured according to the ASTM E96 E method (23° C./85% relative humidity).

Moisture Uptake

The moisture content at saturation of the various formulations is determined by conditioning the films at 85° C. and 85% relative humidity, the temperature and humidity conditions of the damp heat test used in the field of photovoltaics. The moisture content is measured according to the Karl-Fischer volumetric method with an apparatus supplied by Metrohm. The desorption temperatures are adjusted to the type of polyamide used in the formulation (typically 170° C. for a PA-11/PA-12 and 200° C. for a PA-6).

1. A rear protective sheet in a photovoltaic module comprising photovoltaic cells covered with an encapsulant, wherein said rear protective sheet is a multilayer film, wherein said multilayer film comprises:
a CA layer comprising, as predominant polymer, at least one polyamide A exhibiting a mean number of carbon atoms per nitrogen atom of between 4 and 8,
a CB layer comprising: (a) as predominant polymer, at least one polyamide B exhibiting a mean number of carbon atoms per nitrogen atom of between 8 and 15, the polyamide(s) B exhibiting a mean number of carbon atoms per nitrogen atom which is strictly greater than the mean number of carbon atoms per nitrogen atom of the polyamide(s) A, and (b) at least one additive for combating UV radiation,
the CB layer configured to be positioned between the encapsulant and the CA layer.

2. The rear protective sheet as claimed in claim 1, wherein the polyamide A is chosen from: PA-6, PA-8, PA-6.6, PA-4.6, PA-6.10, copolyamide-6.T/6.6, copolyamide 6.I/6.6 and copolyamide 6.T/6.I/6.6, where I represents isophthalic acid and T represents terephthalic acid, and their blends.

3. The rear protective sheet as claimed in claim 1, wherein the polyamide B is chosen from: PA-8, PA-9, PA-11, PA-12, PA-6.10, PA-10.10, PA-10.12, PA-6.12, PA-6.14, PA-6.18, copolyamide 12/10.T, copolyamide 11/10.T or polyamide-12.T, the polyamides preferably having a mean number of 11 to 15 carbon atoms per nitrogen atom.

4. The rear protective sheet as claimed in claim 1, wherein the CA layer is rendered adherent and further comprises a minor amount of polyamides A′ and optionally A″, where:
(i) A′ exhibits a mean number of carbon atoms per nitrogen atom of between 7 and 10 and strictly greater than that of A, and
(ii) A″ exhibits a mean number of carbon atoms per nitrogen atom of between 9 and 18 and strictly greater than that of A′.

5. The rear protective sheet as claimed in claim 1, wherein the CB layer comprises a minor amount of polyamides B′ and B″, which respectively exhibit a mean number of carbon atoms per nitrogen atom of between 4 and 8.5 and strictly less than that of B″ and of between 7 and 10 and strictly less than that of B.

6. The rear protective sheet as claimed in claim 1, wherein the multilayer film further comprises at least one tie layer configured to cause the CB layer to adhere to the CA layer and/or to the encapsulant and/or to cause the CA layer to adhere to the CB layer.

7. The rear protective sheet as claimed in claim 6, wherein the tie layer is chosen from:
one or more copolyamides comprising at least 25% by weight of at least one monomer having a mean number of carbon atoms per nitrogen atom of 4 to 6 and at least 25% by weight of at least one comonomer having a mean number of carbon atoms per nitrogen atom of 9 to 18, and their blends;
one or more homopolyamides of PA-X.Y type where X ranges from 4 to 6 and Y ranges from 8 to 18, and their blends comprising at least 25% by weight of diamine units for which X ranges from 4 to 6 and at least 25% by weight of diacid units for which Y ranges from 8 to 18;
a blend of polyamides;
at least one functionalized polyolefin; and
a blend of polyamide(s) and completely or partially functionalized polyolefin(s).

8. The rear protective sheet as claimed in claim 1, wherein the CA and/or CB layers further comprise at least one impact modifier chosen from functionalized polyolefins.

9. The rear protective sheet as claimed in claim 7, wherein the functionalized polyolefin comprises a copolymer of at least one α-olefin, with at least one comonomer carrying a reactive functional group chosen from a carboxylic acid, a carboxylic anhydride, or an epoxide, and optionally at least one other comonomer not carrying a reactive functional group chosen from: a different α-olefin; a diene; an unsaturated carboxylic acid ester; and a carboxylic acid vinyl ester.

10. The rear protective sheet as claimed in claim 1, wherein the multilayer film has a structure comprising three layers consisting of a CA layer coated with a CB layer on each of face of the CA layer.

11. A photovoltaic module comprising photovoltaic cells protected by an encapsulant, a front protective sheet and a rear protective sheet, in which the rear protective sheet is a multilayer film comprising:
a CA layer comprising, as predominant polymer, at least one polyamide A exhibiting a mean number of carbon atoms per nitrogen atom of between 4 and 8,
a CB layer comprising: (a) as predominant polymer, at least one polyamide B exhibiting a mean number of carbon atoms per nitrogen atom of between 8 and 15, the polyamide(s) B exhibiting a mean number of carbon atoms per nitrogen atom which is strictly greater than the mean number of carbon atoms per nitrogen atom of the polyamide(s) A, and (b) at least one additive for combating UV radiation,
the CB layer being positioned between the encapsulant and the CA layer.
